(19) United States
(12) Patent Application Publication
(10) Pub. No.: US 2012/0003426 A1
(43) Pub. Date: Jan. 5, 2012

(54) DECORATION DEVICE AND METHOD FOR FABRICATING DECORATION DEVICE

(75) Inventor: Kuo-Liang Ying, Taoyuan County (TW)

(73) Assignee: SiPix Chemical Inc., Taoyuan County (TW)

(21) Appl. No.: 12/828,310

(22) Filed: Jul. 1, 2010

(51) Int. Cl. B32B 27/30; C23C 14/34; B32B 37/00; B32B 27/06; B32B 27/38

(52) U.S. Cl. 428/141; 428/421; 428/336; 428/413; 156/60; 156/277; 156/242; 156/230; 204/192.12

(57) ABSTRACT

A decoration device including a housing, an anti-fingerprint layer, an easy-cleaning layer, and an adhesion layer is provided. The anti-fingerprint layer is disposed on the housing and exposed. The easy-cleaning layer is disposed between the housing and the anti-finger print layer, and a material of the easy-cleaning layer includes a polymer containing fluorine. The adhesion layer is disposed between the housing and the easy-cleaning layer.

### BACKGROUND OF THE INVENTION

1. Field of the Invention

The present invention generally relates to a decoration device and a method for fabricating a decoration device, in particular, to a decoration device uneasily stained by dirt or oil material and a method for fabricating a decoration device.

2. Description of Related Art

Conventionally, the illustrations or decorations formed on the surface of the plastic housing are mainly fabricated by spraying process or printing process to present certain effect on the sense of sight. Nevertheless, the spraying process is unfavorable in mass production for the disadvantages of time consumption, process complexity, and inconsistence in thickness. In addition, the conventional spraying process may cause the splashing of sprays containing lead or other heavy metals so that the spraying material is wasted and the problem of pollution is caused.

To solve the abovementioned problem, an in-mold decoration (IMD) technique is provided. The process of the IMD technique includes placing a decoration film that has predetermined decorations into the mold of the injection machine, injecting a melted resin at a side of the film in the mold so that the melted resin and the film are combined, and thereafter ejecting the decorated housing from the mold. Accordingly, a decoration device is completed.

The decoration device is usually used as a housing of a product such that the decoration device can not avoid from contacting by an external element such as a user's finger. The appearance of the decoration device is easily stained by oil material such as an ink or a fingerprint of the user. However, it is not easy to clean the oil material stained on the decoration device. In addition, the user must clean the decoration device frequently, which is not convenient to the user. Therefore, it becomes an important issue to fabricate a decoration device having the property of anti-oil material.

### SUMMARY OF THE INVENTION

Accordingly, the invention is directed to a decoration device capable of reducing the contamination caused by an oil material.

The invention is directed to a method for fabricating a decoration device having anti-fingerprint property.

The invention is further directed to a method for fabricating a decoration device having easy-cleaning property and anti-fingerprint property.

The invention provides a decoration device including a housing, an anti-fingerprint layer, an easy-cleaning layer, and an adhesion layer. The anti-fingerprint layer is disposed on the housing and exposed. The easy-cleaning layer is disposed between the housing and the anti-finger print layer, and a material of the easy-cleaning layer includes a polymer containing fluorine. The adhesion layer is disposed between the housing and the easy-cleaning layer.

According to an embodiment of the invention, a material of the anti-fingerprint layer includes an extinction material such as paraffin, for example.

According to an embodiment of the invention, the anti-fingerprint layer can includes a plurality of diffusion particles, wherein a material of the diffusion particles is selected from SiO2, TiO2, CaCO3, polymethylmethacrylate, paraffin, or a combination thereof.

According to an embodiment of the invention, a material of the anti-fingerprint layer is selected from SiO2, TiO2, or a combination thereof. In addition, the anti-fingerprint layer can have a rough surface away from the housing. The surface roughness of the rough surface is substantially 50 nm.

According to an embodiment of the invention, a thickness of the anti-fingerprint layer is from 150 nm to 200 nm.

According to an embodiment, the polymer containing fluorine has a molar percentage of fluorine to a sum of fluorine plus hydrogen is substantially from 10% to 60%.

According to an embodiment, the polymer containing fluorine is selected from a group consisting of olefinic fluoride, epoxy resin fluoride, aliphatic polyurethane fluoride, and a combination thereof.

According to an embodiment, the polymer containing fluorine comprises polyacrylic fluoride copolymer.

According to an embodiment, the decoration device can further include an ink layer disposed between the easy-cleaning layer and the adhesion layer.

The invention also provides a method for fabricating a decoration device including the following steps. First, a decoration film including a substrate, a releasing layer, an anti-fingerprint layer, an easy-cleaning layer, and an adhesion layer sequentially stacked is provided, wherein a material of the anti-fingerprint layer comprises an extinction material and a material of the easy-cleaning layer comprises a polymer containing fluorine. Next, the decoration film is adhered on a housing through the adhesion layer. The releasing layer and the substrate are subsequently separated from the anti-finger print layer such that the anti-finger print layer is exposed.

According to an embodiment, the extinction material comprises paraffin.

According to an embodiment, the housing is formed by molding, stamping, lamination, or a combination thereof.

According to an embodiment, the anti-fingerprint layer comprises a plurality of diffusion particles. A material of the diffusion particles is selected from SiO2, TiO2, CaCO3, polymethylmethacrylate, paraffin, or a combination thereof.

According to an embodiment, a method for adhering the decoration film on a housing through the adhesion layer and subsequently separate the releasing layer and the substrate from the anti-finger print layer includes an in-mold rollor process, an in-mold film process, a heat transfer printing process, a sublimation heat transfer process, a hot stamping process, an ink jet printing process, a water transfer printing process, or a combination thereof.

The invention also provides a method for fabricating a decoration device. First, a decoration film including a substrate, a releasing layer, an anti-fingerprint layer, and an easy-cleaning layer sequentially stacked is provided, wherein a material of the easy-cleaning layer includes a polymer containing fluorine. The decoration film is adhered on a housing through the adhesion layer. Subsequently, the releasing layer and the substrate are separated from the easy-cleaning layer. An anti-fingerprint layer is formed on the easy-cleaning layer after the releasing layer and the substrate separated from the easy-cleaning layer such that the anti-finger print layer is exposed.

According to an embodiment, a material of the anti-finger print layer includes SiO2, TiO2, or a combination thereof.

According to an embodiment, a method for forming the anti-fingerprint layer includes a sputter process and the anti-fingerprint layer has a rough surface by the sputter process.

According to an embodiment, a method for adhering the decoration film on a housing through the adhesion layer and subsequently separate the releasing layer and the substrate from the anti-finger print layer includes an in-mold rollor process, an in-mold film process, a heat transfer printing process, a sublimation heat transfer process, a hot stamping process, an ink jet printing process, a water transfer printing process, or a combination thereof.

The invention further provides a decoration device including a housing, a decoration layer disposed on the housing, and an adhesion layer disposed between the decoration layer and the housing, wherein the decoration layer has an anti-fingerprint surface away from the adhesion layer and the anti-fingerprint surface is exposed.

According to an embodiment, the decoration layer includes a protection layer and the protection layer has the rough surface.

According to an embodiment, the decoration layer includes a releasing layer and the releasing layer has the rough surface.

According to an embodiment, a surface roughness of the rough surface is in the range of 10 nm to 200 nm.

In view of the above, the decoration device of the invention has an anti-fingerprint layer and an easy-cleaning layer. The anti-fingerprint layer or the exposed layer can be an extinction layer or have rough surface. Any oil material is not easily stained on the decoration device. Alternately, the oil material such as a fingerprint is not easily seen by a user because the extinction effect of the anti-fingerprint layer. In addition, a material of the easy-cleaning layer includes a polymer containing fluorine so that the oil material stained on the decoration device can be easily cleaned.

In order to make the aforementioned and other features and advantages of the invention more comprehensible, embodiments accompanying figures are described in detail below.

Herein, the same or similar reference numbers used in the drawings and the descriptions are referred as the same or similar elements. For clearly describing the concept of the invention, the shapes and the thickness of the elements in the embodiments accompanying with the drawings may not definitely comply with the real circumstance. In addition, the following descriptions are directed to the elements or the combinations thereof, but the elements are not particularly restricted in the contents or the descriptions. Any form or shape known by one skilled in the art is applicable in the invention. Moreover, the description that a material layer disposed on a substrate or disposed on another material layer means that the material layer is directly located on the substrate or the another material layer, and may also mean that some interlayer is interrupted between the material layer and the substrate or between the material layer and the another material layer.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 schematically illustrates a decoration device according to an embodiment of the invention.

FIG. 2 through FIG. 3 schematically illustrate a method for fabricating the decoration device of FIG. 1 according to an embodiment of the invention.

FIG. 4 through FIG. 6 illustrate another method for fabricating the decoration device illustrated in FIG. 1 according to an embodiment of the invention.

FIG. 7 schematically illustrates a decoration device according to another embodiment of the invention.

FIG. 8 to FIG. 10 illustrate further another method for fabricating a decoration device according to an embodiment of the invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

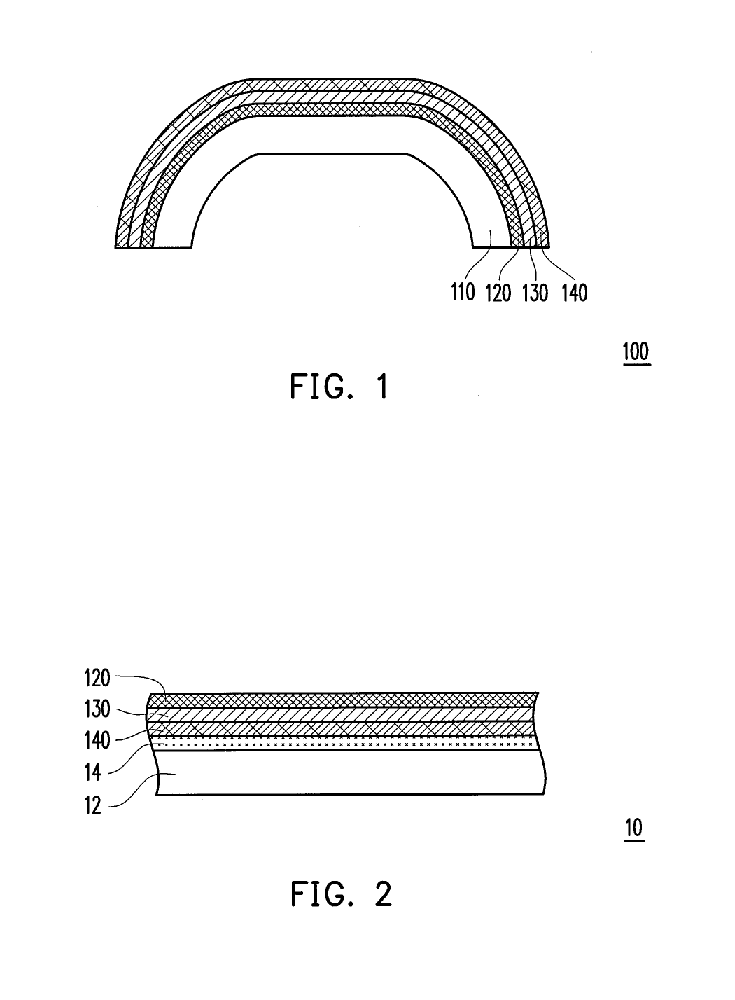

FIG. 1 schematically illustrates a decoration device according to an embodiment of the invention. Referring to FIG. 1, a decoration device 100 includes a housing 110, an adhesion layer 120, an easy-cleaning layer 130, and an anti-fingerprint layer 140. The adhesion layer 120 directly contacts the housing 110 while the easy-cleaning layer 130 and the anti-fingerprint layer 140 are sequentially disposed on the adhesion layer 120. Therefore, the easy-cleaning layer 130 is sandwiched between the anti-fingerprint layer 140 and the adhesion layer 120 and the anti-fingerprint layer 140 is exposed.

The decoration device 100 has the anti-fingerprint layer 140 which is the outer layer so that a dirt or oil material such as a fingerprint is not easily stained thereon. Accordingly, the appearance is not dirtied and a user does not need to frequently clean the decoration device 100, which is convenient to the user. In addition, once the dirt or oil material such as the fingerprint is stained on the decoration device 100, the dirt or oil material can be easily removed due to the easy-cleaning property of the easy-cleaning layer 130. Therefore, the decoration device 100 can remain beautiful and look like a new one.

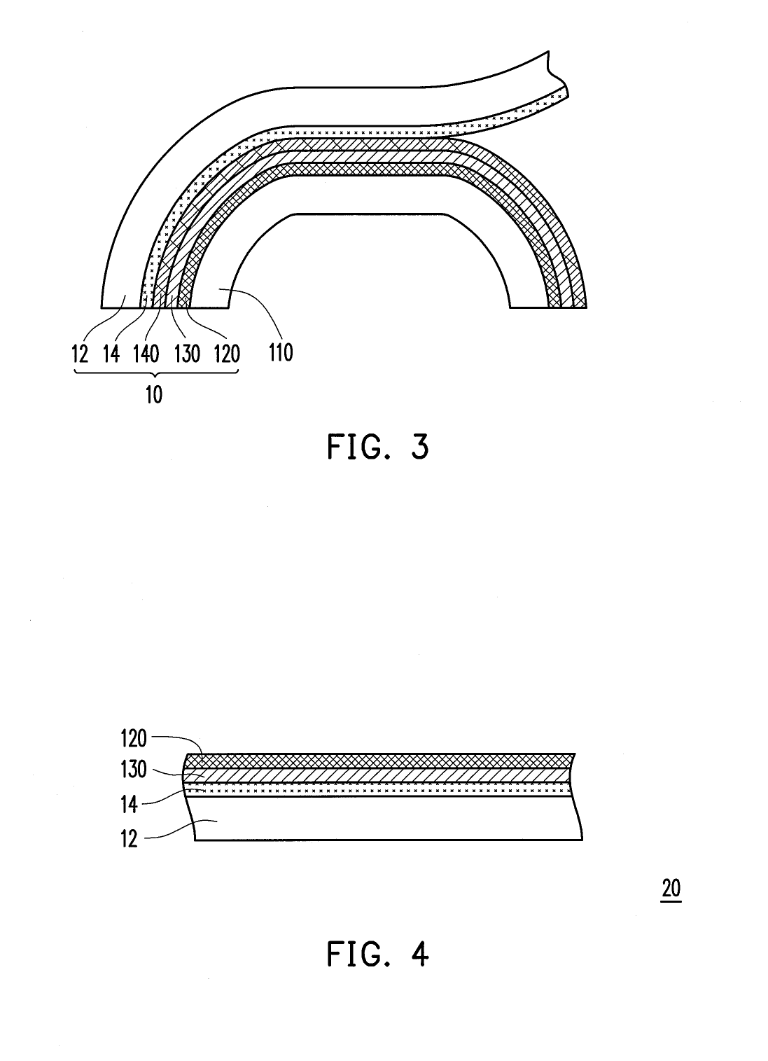

Specifically, FIG. 2 through FIG. 3 schematically illustrate a method for fabricating the decoration device 100 of FIG. 1 according to an embodiment of the invention. Referring to FIG. 2, a decoration film 10 is firstly provided, wherein the decoration film 10 mainly includes a substrate 12, a releasing layer 14, an anti-fingerprint layer 140, an easy-cleaning layer 130, and an adhesion layer 120. The releasing layer 14, the anti-fingerprint layer 140, the easy-cleaning layer 130, and the adhesion layer 120 are sequentially disposed on the substrate 12.

Generally, a material of the substrate 12, which is a flexible substrate, can be polyethylene terephthalate (PET), polyethylene naphthalate (PEN), polyethylene glycol-co-cyclohexane-1,4 dimethanol terephthalate (PETG), thermalplastic polyurethane (TPU), polyurethane (PU), polypropylene (PP), polycarbonate (PC), amorphous polyethylene terephthalate (A-PET), polyvinyl chloride (PVC), Polystyrene (PS), triacetyl cellulose (TAC), polymethylmethacrylate (PMMA), methylmethacrylate-styrene (MMA-st, MS) copolymer, cyclo olefin copolymer (COC) and a combination thereof, but the invention is not restricted herein.

In addition, the releasing layer 14 directly contacting the substrate 12 is usually a thin film with low surface tension which can be made of a wax, a paraffin, or silicone, or an impermeable thin film with high smoothness which can be made of an irradiation curable multi-functional acrylic, silicone acrylate, epoxy, vinyl, allyl vinyl compound, unsaturated polyester or a mixture thereof. A material of the releasing layer 14 can be selected from a polycondensate, a copolymer, a blend, or a mixture consisting of epoxy, polyurethane, polyimide, polyamide, hexa methoxymethyl melamine-formaldehyde, urea-formaldehyde, phenol-formaldehyde, and a combination thereof. Accordingly, the releasing layer 14 can provide a removable effect or a temporary adhesion effect.

For having the anti-fingerprint function, an extinction material such as paraffin, for example, can be used as a material to fabricate the anti-fingerprint layer 140. Alternately, the anti-fingerprint layer 140 can includes a plurality of diffusion particles (not shown) for having the anti-fingerprint function. For example, a material of the diffusion particles (not shown) can be selected from SiO2, TiO2, CaCO3, polymethylmethacrylate, paraffin, or a combination thereof. Certainly, the anti-fingerprint layer 140 can be an extinction material layer having a plurality of diffusion particles distributed therein in another embodiment.

A material of the easy-cleaning layer 130 includes a polymer containing fluorine. Such material can be selected from a group consisting of olefinic fluoride, epoxy resin fluoride, aliphatic polyurethane fluoride, and a combination thereof. In an embodiment, the polymer containing fluorine includes polyacrylic fluoride copolymer. In the present embodiment, a molar percentage of fluorine to a sum of fluorine plus hydrogen in the easy-cleaning layer 130 is substantially from 10% to 60%.

The adhesion layer 120 can be formed by the material selected from polyacrylate, polymethacrylate, polystyrene, polycarbonate, polyurethane, polyester, polyamide, epoxy resin, ethylene vinylacetate copolymer (EVA) or thermoplastic elastomer or a copolymer, blend, or combination thereof. Herein, the anti-fingerprint layer 140 and the easy-cleaning layer 130 are served as decoration layers while the substrate 12 and the releasing layer 14 are used for temporary carrying the decoration layers during the fabricating process in the present embodiment.

Specifically, referring to FIG. 3, a decoration process is performed to adhere the decoration film 10 on a housing 110 through the adhesion layer 120. During the decoration process, the substrate 12 and the releasing layer 14 are removed from the anti-fingerprint layer 140 and thus the decoration device 100 illustrated in FIG. 1 can be fabricated. That is to say, the anti-fingerprint layer 140 is the outer layer of the decoration device 100 and the easy-cleaning layer 130 is sandwiched between the anti-fingerprint layer 140 and the adhesion layer 120. In addition, the adhesion layer 120 directly contacts the housing 110.

In the present embodiment, the decoration process can be an in-mold decoration (IMD) technique, a heat transfer printing process, a sublimation heat transfer process, a hot stamping process, an ink-jet printing process, a water transfer printing process, and the like, wherein the IMD technique substantially includes an in-mold labelling (IML) process, an in-mold film (IMF) process, an in-mold roller (IMR) process, or the like. Namely, the housing 110 can be fabricated by a molding process such as an injection molding process, a thermoforming process, a compression molding process, a blow molding process, a thermal printing process, an injection molding process, a compression process, or a combination thereof. Specifically, a material of the housing 110 includes polycarbonate (PC), polypropylene (PP), polymethylmethacrylate (PMMA), methylmethacrylate-styrene (MMA-st, MS) copolymer, MS, acrylonitrile butadiene styrene (ABS), polystyrene (PS), polyethylene terephthalate (PET), polyoxymethylene (POM) or a combination thereof. However, the invention is not restricted thereto and other known processes capable of transferring the decoration layers such as the anti-fingerprint layer 140 and the easy-cleaning layer 130 from the substrate 12 onto the housing 110 can be applied.

In the decoration device 100, the anti-fingerprint layer 140 can be formed by the extinction material or have a plurality of diffusion particles distributed therein. It is known that the extinction material interferes the light irradiated thereon. Therefore, any dirt or contamination such as the fingerprint stained on the anti-fingerprint layer 140 is not easily seen due to the extinction characteristic. In addition, in the case that a plurality of diffusion particles is distributed in the anti-fingerprint layer 140, the diffusion particles (not shown) are capable of diffusing the light irradiated thereon so as to reduce the possibility that a user see the dirt or contamination such as the fingerprint stained on the anti-fingerprint layer 140. Accordingly, the disposition of the anti-fingerprint layer 140 is conducive to maintain the appearance of the decoration device 100 by interfering the light on the surface of the decoration device 100.

Furthermore, the easy-cleaning layer 130 having the composition of the polymer containing fluorine is conducive to provide specific interface property such that the dirt or oil material stained on the decoration device 100 can be easily removed. Accordingly, the decoration device 100 is easily to be cleaned so as to maintain beauty. Based on the high bonding energy of the material containing fluorine, the surface energy of the polymer is reduced and the contacting angle of water dropping on the polymer is increased. Therefore, the polymer containing fluorine has enhanced hydrophobic effect so that water drop can be rapidly slipped out the easy-cleaning layer 130. That is to say, the easy-cleaning layer 130 can not merely have the easy-cleaning property, but also have the hydrophobic property.

Specifically, the method for forming the anti-fingerprint layer 140 is not restricted in combining with the decoration process and another method for forming the same is exemplified in the following. Certainly, the methods depicted in the embodiments does not intend to limit the invention and other suitable processes can be applied for forming the anti-fingerprint layer 140.

FIG. 4 through FIG. 6 illustrate another method for fabricating the decoration device illustrated in FIG. 1 according to an embodiment of the invention. Referring to FIG. 4, a decoration film 20 including the substrate 12, the releasing layer 14, the easy-cleaning layer 130, and the adhesion layer 120 is provided. It is noted that the difference between the decoration film 20 and the decoration film 10 mainly lies in that the decoration film 20 does not have the anti-fingerprint layer 140 as shown in FIG. 2. Therefore, the materials and the methods for forming the substrate 12, the releasing layer 14, the easy-cleaning layer 130, and the adhesion layer 120 can be referred to the foregoing embodiment.

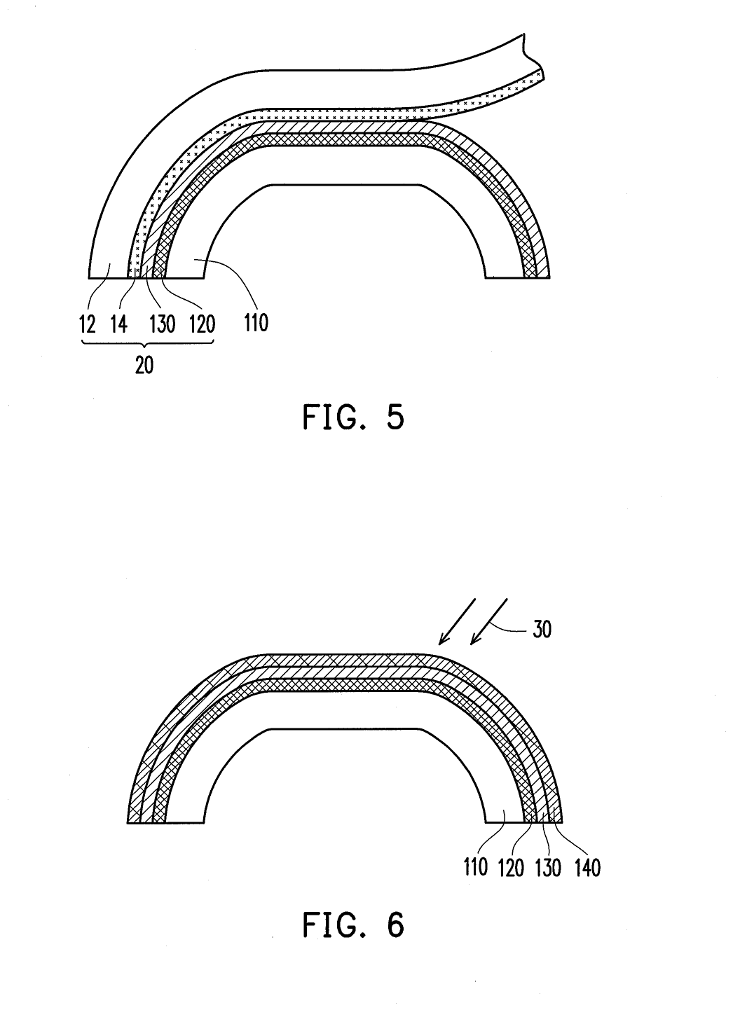

Next, referring to FIG. 5, a decoration process is performed to adhere the easy-cleaning layer 130 on the housing 110 through the adhesion layer 120. Herein, the decoration process which is similar to that depicted in the foregoing embodiment can be a heat transfer printing process, a sublimation heat transfer process, a hot stamping process, an ink jet printing process, a water transfer printing process, the an in-mold labelling (IML) process, an in-mold film (IMF) process, an in-mold roller (IMR) process, or the like. During the decoration process, the substrate 12 and the releasing layer 14 are removed from the easy-cleaning layer 130 so that the easy-cleaning layer 130 is the outer layer of the semi-fabricated product.

Subsequently, referring to FIG. 6, a surface treating process 30 such as a physical vapor deposition (PVD), a chemical vapor deposition (CVD) or an evaporation process or the combinations thereof is performed on the easy-cleaning layer 130 of the semi-fabricated product to form the anti-fingerprint layer 140. Accordingly, the decoration device 100 illustrated in FIG. 1 is fabricated. In an embodiment, a material of the anti-fingerprint layer 140 can be selected from SiO2, TiO2, or a combination thereof. In addition, the anti-fingerprint layer 140 can have a rough surface away from the housing 110 by the surface treating process, i.e. the sputter process. Specifically, a surface roughness of the anti-fingerprint layer 140 can be about 50 nm according to an observation of atomic force microscope (AFM) and a thickness of the anti-finger layer 140 can be from 10 nm to 200 nm. However, the thickness of the anti-fingerprint layer 140 is not restricted here and can be modulated based on specific requirement.

It is noted that the rough surface of the anti-fingerprint layer 140 conduces to reduce the area of the dirt or the contamination contacting the anti-fingerprint layer 140. Accordingly, the dirt or the contamination such as the fingerprint is not easily stained on the anti-fingerprint layer 140 so that the anti-fingerprint function can be achieved and the decoration device 100 can maintain the clear of the appearance. In addition to the anti-fingerprint layer 140, the easy-cleaning layer 130 is further conducive to prevent the decoration device 100 from being dirtied so that the decoration device 100 can keep a desirable appearance.

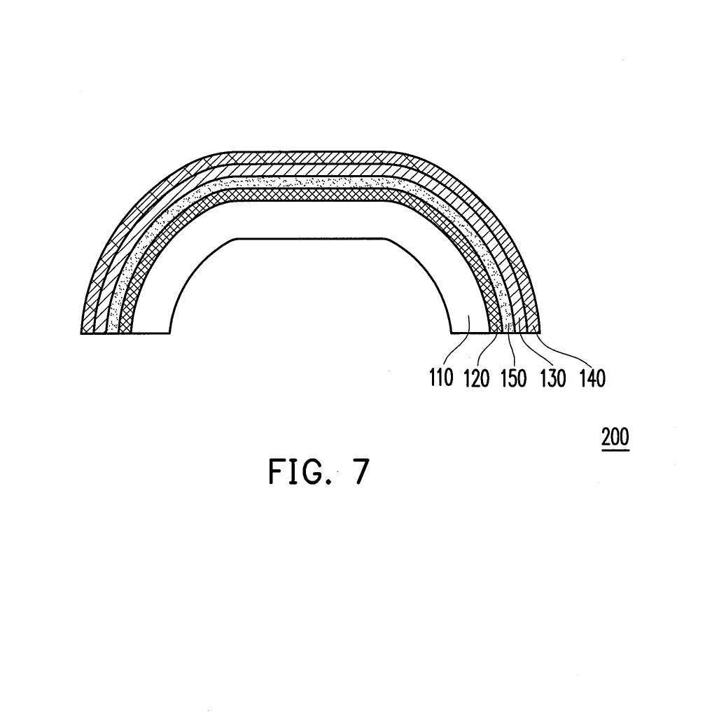

Generally, the decoration device 100 can further have other decoration layers for having various effects on the sense of sight. For example, FIG. 7 schematically illustrates a decoration device according to another embodiment of the invention. Referring to FIG. 7, the decoration device 200 is similar to the decoration device 100 mentioned above while the difference between the decoration device 100 and the decoration device 200 lies in that the decoration device 200 further has another decoration layer 150 disposed between the easy-cleaning layer 130 and the adhesion layer 120. Herein, the disposition locations and the materials of the housing 110, the adhesion layer 120, the easy-cleaning layer 130, and the anti-fingerprint layer 140 can be referred to the aforesaid embodiment and are not reiterated. In the present embodiment, the decoration layer 150 can have a single-layer structure, a multi-layer structure, or a patterned structure so that the decoration device 200 can have required effects on the sense of sight by the disposition of the decoration layer 150. For example, different gloss, different colors or patterns can be constituted by the decoration layer 150.

For fabricating the decoration device 200, any of the method illustrated in FIGS. 2 and 3 and the method illustrated in FIGS. 4-6 can be applied. Specifically, if the method illustrated in FIGS. 2 and 3 is applied, the decoration film 10 shown in FIG. 2 can further include the decoration layer 150 disposed between the easy-cleaning layer 160 and the adhesion layer 120. Alternately, if the method illustrated in FIGS. 4-6 is applied, the decoration film 20 shown in FIG. 4 can further include the decoration layer 150 disposed between the easy-cleaning layer 160 and the adhesion layer 120. That is to say, the decoration layer 150 is formed in a decoration film and then disposed on the housing 110 by performing a decoration process. In the present embodiment, the decoration layer 150 can be an ink layer, a metal layer, a hologram layer, or any combination thereof and the decoration layer 150 can be selectively disposed merely on a potion of the substrate of the decoration film or completely on the whole surface of the substrate of the decoration film.

In an embodiment, the ink layer served as the decoration layer 150 can be a colorful ink layer, a black ink layer, or a white ink layer. The ink layer can be formed by any suitable printing process such as a gravure printing, process, a screen printing process, a flexographic printing process, an offset printing, a reverse printing process, an ink jet printing process while a material of the ink layer can be sublimation type transferring ink, heat-melted type transferring ink, UV-type transferring ink, and the like. If a metal layer is served as the decoration layer 150, a metal material such as Al, Cu, Zn, Sn, Mo, Ni, Cr, Ag, Au, Fe, In, Tl, Ti, Ta, W, Rh, Pd, Mg, Pt, any alloy thereof, or a combination thereof can be used to form the decoration layer 150. The method for forming the metal layer includes, but not restricted to coating, laminating, electroplating, sputtering, vacuum evaporating, or a combination thereof. If the decoration layer 150 is a hologram layer, a layer of microstructures with a metal layer conformed thereto is provided between the adhesion layer 120 and the easy-cleaning layer 130.

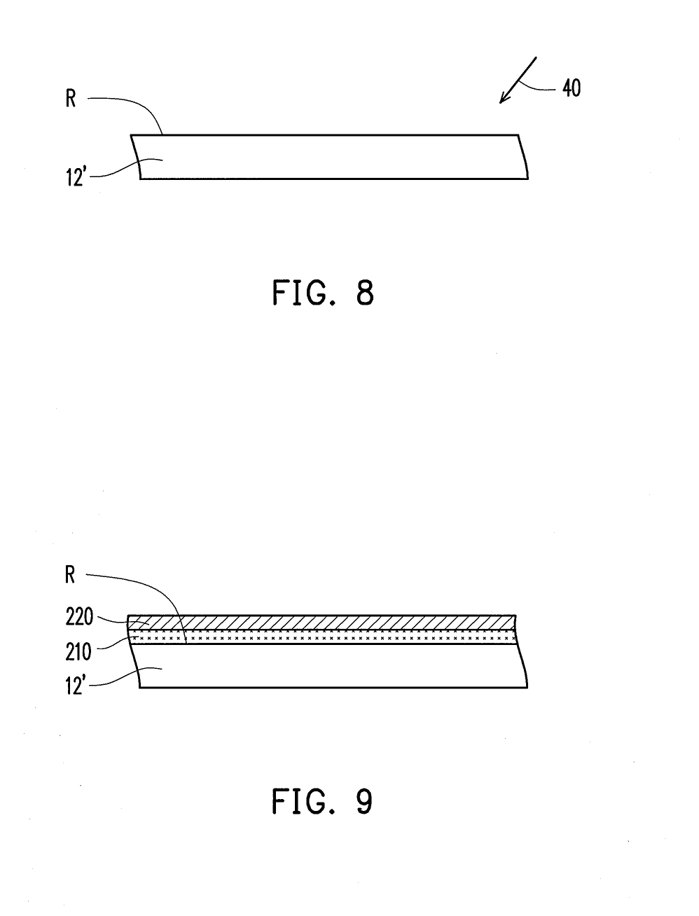

It is noted that the anti-fingerprint layer 140 may not fabricated by performing the surface treating process 30 on the easy-cleaning layer 130 as described above for providing the anti-fingerprint function. FIG. 8 to FIG. 10 illustrate further another method for fabricating a decoration device according to an embodiment of the invention. Referring to FIG. 8, a substrate 12′ is provided and a surface treating process 40 is performed on the substrate 12′. The surface treating process 40 can be a chemical vapor deposition (CVD) process, a physical vapor deposition (PVD) process, or the like and the surface treating process 40 is performed for forming a plurality of nano-particles (not shown) on the substrate 12′. In the present embodiment, the material of the nano-particles (not shown) can be selected from SiO₂, TiO₂, or a combination thereof. It is noted that the substrate 12′ has a rough surface R due to the nano-particles (not shown). In one embodiment, a surface roughness of the rough surface R is in the range of 10 nm to 200 nm.

Thereafter, referring to FIG. 9, a decoration layer 210 and an adhesion layer 220 are sequentially formed on the rough surface R of the substrate 12′. For example, the method for forming the decoration layer 210 and the adhesion layer 220 can be a printing process or the like used in the above-mentioned embodiments and the method for forming the decoration layer 210 and the adhesion layer 220 are not described in detail herein. The decoration layer 210 may include at least one material layer such as a releasing layer, a protection layer, an ink layer, a metal layer, an easy-cleaning layer, a hologram layer, etc. and the characteristics and the numbers of the material layers are not restricted in the invention. Moreover, the material of the adhesion layer 220 can be referred to the above-mentioned embodiments.

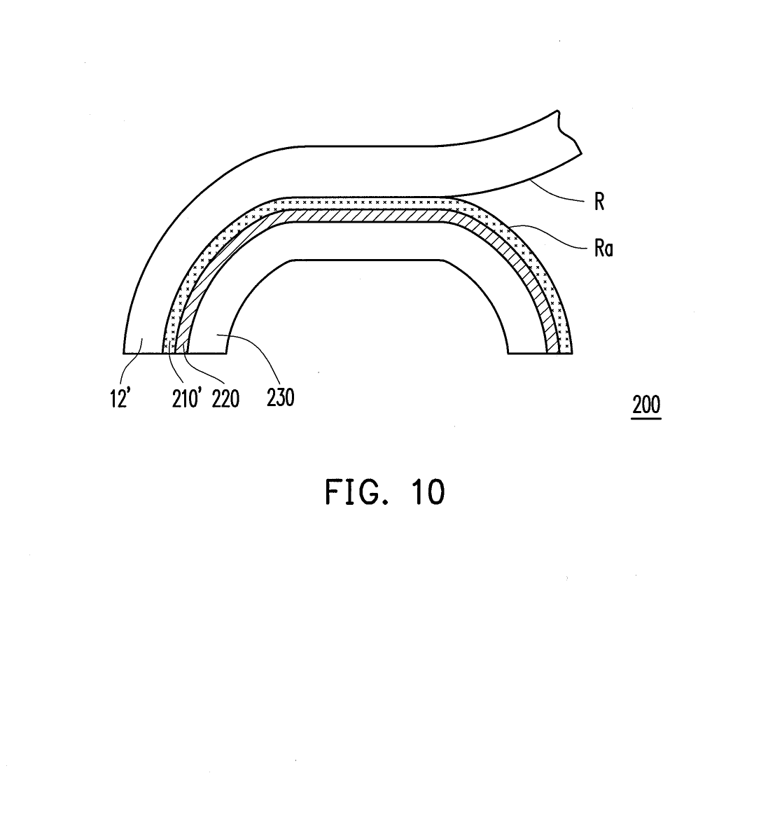

Next, referring to FIG. 10, a decoration process is performed to adhered the decoration layer 210 on a housing 230 through the adhesion layer 220 and then the substrate is removed so that a decoration device 200 including the housing 230, the adhesion layer 220, and the decoration layer 210′ is formed. Herein, the decoration process can be any decoration process described above. It is noted that the substrate 12′ has the rough surface R so that the decoration layer 210′ can have an anti-fingerprint surface Ra corresponding to the rough surface R at a side adjacent to the substrate 12′ and away from the adhesion layer 220. In the present embodiment, the rough surface R is achieved by forming a plurality of nano-particles on the substrate 12′ so that the side of the decoration layer 210′ adjacent to the substrate 12′ may have a rough structure corresponding to the rough surface R. Any oil, dirt, or fingerprint is difficultly stained on a surface having the rough structure because a size of the rough structure is, for example, 10 nm to 200 nm, which achieves the anti-fingerprint function so that the surface at the side of the decoration layer 210′ away from the adhesion layer 220 is called the anti-fingerprint surface Ra herein. Specifically, the anti-fingerprint surface Ra is exposed in the decoration device 200 to provide a proper anti-fingerprint function. It is noted that any additional surface treating process is not required after the decoration process to achieve the anti-fingerprint function according to the present embodiment.

It is noted that the decoration layer 210′ can include a plurality of material layers, wherein one of the material layers most away from the adhesion layer 220 can have the anti-fingerprint surface Ra. For example, the material layer having the anti-fingerprint surface Ra can be the protection layer, the easy-cleaning layer, or any material layer located at the outer side of the decoration device 200. For example, the releasing layer can be selectively remained on the housing 230 after the substrate 12′ is removed from the housing 230 so that the releasing layer can be a part of the decoration layer 210′ and the material layer having the anti-fingerprint surface Ra can be the releasing layer. Alternately, when the releasing layer is removed from the housing 230 accompanying with the substrate 12′, the decoration layer 210′ does not include the releasing layer and the material layer having the anti-fingerprint surface Ra can be the exposed material layer.

In summary, the decoration device of the invention includes at least an anti-fingerprint layer and an easy-cleaning layer. The anti-fingerprint layer may have extinction property to interfere the light on the surface of the decoration. Therefore, any dirt or oil material stained on the anti-fingerprint layer may not easily be seen. In addition, the anti-fingerprint layer or the exposed layer in the decoration device may have a rough surface so that the dirt or oil material would not be easily stained thereon to achieve the anti-fingerprint effect. Furthermore, the easy-cleaning layer can provide the easy-cleaning effect such that the decoration device of the invention can be easily cleaned to maintain clear appearance.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A decoration device, comprising:
a housing;
an anti-fingerprint layer disposed on the housing and being exposed;
an easy-cleaning layer disposed between the housing and the anti-finger print layer, and a material of the easy-cleaning layer comprises a polymer containing fluorine; and
an adhesion layer disposed between the housing and the easy-cleaning layer.

2. The decoration device according to claim 1, wherein a material of the anti-fingerprint layer comprises an extinction material.

3. The decoration device according to claim 2, wherein the extinction material comprises paraffin.

4. The decoration device according to claim 1, wherein the anti-fingerprint layer comprises a plurality of diffusion particles.

5. The decoration device according to claim 4, wherein a material of the diffusion particles is selected from SiO2, TiO2, CaCO3, polymethylmethacrylate, paraffin, or a combination thereof.

6. The decoration device according to claim 1, wherein a material of the anti-fingerprint layer is selected from SiO2, TiO2, or a combination thereof.

7. The decoration device according to claim 6, wherein the anti-fingerprint layer has a rough surface away from the housing.

8. The decoration device according to claim 7, wherein a surface roughness of the rough surface is substantially 50 nm.

9. The decoration device according to claim 1, wherein a thickness of the anti-fingerprint layer is from 150 nm to 200 nm.

10. The decoration device according to claim 1, wherein the polymer containing fluorine has a molar percentage of fluorine to a sum of fluorine plus hydrogen is substantially from 10% to 60%.

11. The decoration device according to claimed in claim 1, wherein the polymer containing fluorine is selected from a group consisting of olefinic fluoride, epoxy resin fluoride, aliphatic polyurethane fluoride, and a combination thereof.

12. The decoration device according to claim 1, wherein the polymer containing fluorine comprises polyacrylic fluoride copolymer.

13. The decoration device according to claim 1, further comprising an ink layer disposed between the easy-cleaning layer and the adhesion layer.

14. A method for fabricating a decoration device comprising:
providing a decoration film comprising a substrate, a releasing layer, an anti-fingerprint layer, an easy-cleaning layer, and an adhesion layer sequentially stacked, wherein a material of the anti-fingerprint layer comprises an extinction material and a material of the easy-cleaning layer comprises a polymer containing fluorine; and
adhering the decoration film on a housing through the adhesion layer and subsequently separate the releasing layer and the substrate from the anti-finger print layer such that the anti-finger print layer is exposed.

15. The method according to claim 14, wherein the extinction material comprises paraffin.

16. The method according to claim 14, wherein the housing is formed by molding, stamping, lamination, or a combination thereof.

17. The method according to claim 1, wherein the anti-fingerprint layer comprises a plurality of diffusion particles.

18. The method according to claim 17, wherein a material of the diffusion particles is selected from SiO2, TiO2, CaCO3, polymethylmethacrylate, paraffin, or a combination thereof.

19. The method according to claim 14, wherein a method for adhering the decoration film on a housing through the adhesion layer and subsequently separate the releasing layer and the substrate from the anti-finger print layer comprises an in-mold rollor process, an in-mold film process, a heat transfer printing process, a sublimation heat transfer process, a hot stamping process, an ink-jet printing process, a water transfer printing process, or a combination thereof.

20. A method for fabricating a decoration device comprising:
providing a decoration film comprising a substrate, a releasing layer, an anti-fingerprint layer, and an easy-cleaning layer sequentially stacked, wherein a material of the easy-cleaning layer comprises a polymer containing fluorine;
adhering the decoration film on a housing through the adhesion layer and subsequently separate the releasing and the substrate from the easy-cleaning layer; and
forming an anti-fingerprint layer on the easy-cleaning layer after separating the releasing layer and the substrate from the easy-cleaning layer such that the anti-finger print layer is exposed.

21. The method according to claim 20, wherein a material of the anti-finger print layer comprises SiO2, TiO2, or a combination thereof.

22. The method according to claim 20, wherein a method for forming the anti-fingerprint layer comprises a sputter process and the anti-fingerprint layer has a rough surface by the sputter process.

23. The method according to claim 20, wherein a method for adhering the decoration film on a housing through the adhesion layer and subsequently separate the releasing layer and the substrate from the anti-finger print layer comprises an in-mold rollor process, an in-mold film process, a heat transfer printing process, a sublimation heat transfer process, a hot stamping process, an ink jet printing process, a water transfer printing process, or a combination thereof.

24. A decoration device, comprising:
a housing;
a decoration layer disposed on the housing; and
an adhesion layer disposed between the decoration layer and the housing, wherein the decoration layer has an anti-fingerprint surface away from the adhesion layer and the anti-fingerprint surface is exposed.

25. The decoration device according to claim 24, wherein the decoration layer includes a protection layer and the protection layer has the rough surface.

26. The decoration device according to claim 25, wherein a surface roughness of the rough surface is in the range of 10 nm to 200 nm.

27. The decoration device according to claim 24, wherein the decoration layer includes a releasing layer and the releasing layer has the rough surface.

28. The decoration device according to claim 27, wherein a surface roughness of the rough surface is in the range of 10 nm to 200 nm.
